(19) United States
(12) Patent Application Publication
(10) Pub. No.: US 2018/0356725 A1
(43) Pub. Date: Dec. 13, 2018

(54) RADIATION-SENSITIVE COMPOSITION AND PATTERN-FORMING METHOD

(71) Applicant: JSR CORPORATION, Tokyo (JP)

(72) Inventor: Kazuki KASAHARA, Tokyo (JP)

(73) Assignee: JSR CORPORATION, Tokyo (JP)

(21) Appl. No.: 16/104,163

(22) Filed: Aug. 17, 2018

Related U.S. Application Data
(63) Continuation of application No. PCT/JP2017/004281, filed on Feb. 6, 2017.
(60) Provisional application No. 62/297,452, filed on Feb. 19, 2016.

(51) Int. Cl. G03F 7/004

(52) U.S. Cl. CPC G03F 7/0047; G03F 7/16; G03F 7/0045

(57) ABSTRACT

A radiation-sensitive composition includes: particles including a metal oxide as a principal component; and a radiation-sensitive base-generating agent, wherein a percentage content of metal atoms included in the composition with respect to an entirety of metal atoms and metalloid atoms included in the composition is no less than 50 atom %. A metal atom constituting the metal oxide preferably includes a zirconium atom, a hafnium atom, a chromium atom, a nickel atom, a cobalt atom, a tin atom, an indium atom, a titanium atom, a ruthenium atom, a tantalum atom, a tungsten atom, an iron atom, a copper atom, a zinc atom, an aluminum atom, a gallium atom, a thallium atom, a bismuth atom or a combination thereof. A pattern-forming method includes: applying the aforementioned radiation-sensitive composition on one face side of a substrate to form a film; exposing the film; and developing the film exposed.

### CROSS-REFERENCE TO RELATED APPLICATIONS

The present application is a continuation application of International Application No. PCT/JP2017/004281, filed Feb. 6, 2017, which claims priority to U.S. Provisional Patent Application No. 62/297,452, filed Feb. 19, 2016. The contents of these applications are incorporated herein by reference in their entirety.

### BACKGROUND OF THE INVENTION

### Field of the Invention

The present invention relates to a radiation-sensitive composition and a pattern-forming method.

### Discussion of the Background

A typical radiation-sensitive resin composition for use in microfabrication by lithography generates an acid upon an exposure to an electromagnetic wave such as a far ultraviolet ray (for example, an ArF excimer laser beam, a KrF excimer laser beam and the like) and an extreme ultraviolet ray (EUV), a charged particle ray such as an electron beam, or the like at a light-exposed region. A chemical reaction in which the acid serves as a catalyst causes the difference in rates of dissolution in a developer solution, between light-exposed regions and light-unexposed regions to form a pattern on a substrate. The pattern thus formed can be used as a mask or the like in substrate processing.

Miniaturization in processing techniques has been accompanied by demands for improved resist performances of such radiation-sensitive compositions. Types, molecular structures and the like of polymers, acid-generating agents and other components to be used in a composition have been studied in order to address the demands, and combinations thereof have also been extensively studied (refer to Japanese Unexamined Patent Application, Publication Nos. H11-125907, H8-146610, and 2000-298347).

Currently, microfabrication of a pattern has thus proceeded to a level for a line width of no greater than 40 mm

### SUMMARY OF THE INVENTION

According to an aspect of the present invention, a radiation-sensitive composition includes: particles including a metal oxide as a principal component; and a radiation-sensitive base-generating agent. A percentage content of metal atoms included in the composition with respect to an entirety of metal atoms and metalloid atoms included in the composition is no less than 50 atom %.

According to another aspect of the present invention, a pattern-forming method includes: applying the aforementioned radiation-sensitive composition on one face side of a substrate to form a film; exposing the film; and developing the film exposed.

### DESCRIPTION OF EMBODIMENTS

According to an embodiment of the invention, a radiation-sensitive composition comprises: particles comprising a metal oxide as a principal component (hereinafter, may be also referred to as “(A) particles” or “particles (A)”); and a radiation-sensitive base-generating agent (hereinafter, may be also referred to as “(B) base-generating agent” or “base-generating agent (B)”), wherein a percentage content of metal atoms comprised in the composition with respect to an entirety of metal atoms and metalloid atoms comprised in the composition is no less than 50 atom %.

According to another embodiment of the invention, a pattern-forming method comprises: applying the aforementioned radiation-sensitive composition on one face side of a substrate to form a film; exposing the film; and developing the film exposed.

The term “metal oxide” as referred to means a compound that comprises at least a metal atom and an oxygen atom. The term “principal component” as referred to means a component which is of the highest content, for example, a component the content of which is no less than 50% by mass. The term “particles” as referred to means, for example, a substance that has a mean particle diameter of no less than 1 nm. The term “metalloid atom” as referred to means a boron atom, a silicon atom, a germanium atom, an arsenic atom, an antimony atom, and a tellurium atom.

The radiation-sensitive composition and the pattern-forming method according to the embodiments of the present invention enable a pattern superior in resolution to be formed with high sensitivity. Therefore, these can be suitably used for a processing process of semiconductor devices, and the like, in which further progress of miniaturization is expected in the future. Hereinafter, the embodiments will be explained in detail.

### Radiation-Sensitive Composition

The radiation-sensitive composition of an embodiment of the present invention includes (A) particles and (B) a base-generating agent. The radiation-sensitive composition may also include an organic solvent (hereinafter, may be also referred to as “(C) solvent” or “solvent (C)”) as a favorable component, and may also include other optional components within a range not leading to impairment of the effects of the present invention. A percentage content of metal atoms included in the radiation-sensitive composition with respect to an entirety of metal atoms and metalloid atoms included in the composition is no less than 50 atom %.

Due to including the particles (A) and the base-generating agent (B), with the percentage content of the metal atoms with respect to the entirety of metal atoms and metalloid atoms included in the composition being no less than the lower limit, the radiation-sensitive composition enables a pattern superior in resolution to be formed with high sensitivity. Although not necessarily clarified and without wishing to be bound by any theory, the reason for achieving the effects described above due to the radiation-sensitive composition having the aforementioned constitution is inferred as in the following, for example. Specifically, in a film formed from the radiation-sensitive composition, the metal atoms included in the particles (A) and the like in the light-exposed regions absorb exposure light to generate secondary electrons. An action of the secondary electrons and the like decomposes the base-generating agent (B) to generate a base. The base serves as a catalyst that promotes a reaction of forming —OH from an oxygen atom bonding to the metal atom in the metal oxide that is the principal component of the particles (A), as well as a dehydrative condensation reaction of forming —O from two —OHs. Accordingly, in the light-exposed region of the film, the base promotes the aforementioned two reactions similar to a sol-gel condensation reaction, and consequently a condensation product is formed in which a plurality of metal oxides are connected through —O—. As a result, a contrast is provided in rates of dissolution in the developer solution between the light-exposed regions and the light-unexposed regions of the film. In addition, the radiation-sensitive composition is believed to be superior in sensitivity and resolution due to the superior efficiency of generation of the base by the secondary electrons, the superior efficiency of the reaction of forming the condensation product during which the base serves as the catalyst, appropriately small condensation products thus formed, and the like, as compared to those of the conventional radiation-sensitive composition including a radiation-sensitive acid-generating agent. Furthermore, the radiation-sensitive composition is believed to be further superior in the sensitivity and resolution due to the percentage content of the metal atoms with respect to the entirety of the metal atoms and the metalloid atoms being no less than the aforementioned lower limit, resulting in inhibition of absorption of the exposure light by the metalloid atoms, and in turn enabling generation of the secondary electrons by the metal atoms to be promoted.

The lower limit of the percentage content of the metal atoms with respect to the entirety of the metal atoms and the metalloid atoms in the radiation-sensitive composition is 50 atom %, preferably 70 atom %, more preferably 90 atom %, and still more preferably 99 atom %. Due to the percentage content of the metal atoms being no less than the lower limit, more effective promotion of the generation of the secondary electrons by the metal atoms is enabled, whereby the sensitivity and resolution of the radiation-sensitive composition can be further improved. It is to be noted that the percentage content of the metal atoms may be 100 atom %.

### (A) Particles

The particles (A) include a metal oxide as a principal component. It is to be noted that since the particles (A) include the metal oxide as the principal component, the particles (A) contribute also to improving etching resistance of a pattern formed from the radiation-sensitive composition of the embodiment of the present invention.

The lower limit of a mean particle diameter of the particles (A) is preferably 1.1 nm. Meanwhile, the upper limit of the mean particle diameter of the particles (A) is preferably 20 nm, more preferably 10 nm, still more preferably 3.0 nm, and particularly preferably 2.0 nm.

When the mean particle diameter of the particles (A) falls within the above range, more effective promotion of the generation of the secondary electrons by the particles (A) is enabled, whereby the sensitivity and resolution of the radiation-sensitive composition can be further improved. The “mean particle diameter” as referred to herein means a harmonic mean particle size on the basis of scattered light intensity, as measured by DLS (Dynamic Light Scattering) using a light scattering measurement device.

### Metal Oxide

A metal atom constituting the metal oxide that is the principal component of the particles (A) is exemplified by metal atoms from groups 3 to 15. Of these, metal atoms from group 4 such as a titanium atom, a zirconium atom and a hafnium atom, metal atoms from group 5 such as a tantalum atom, metal atoms from group 6 such as a chromium atom and a tungsten atom, metal atoms from group 8 such as an iron atom and a ruthenium atom, metal atoms from group 9 such as a cobalt atom, metal atoms from group 10 such as a nickel atom, metal atoms from group 11 such as a copper atom, metal atoms from group 12 such as a zinc atom, metal atoms from group 13 such as an aluminum atom, a gallium atom, an indium atom and a thallium atom, metal atoms from group 14 such as a tin atom, and metal atoms from group 15 such as a bismuth atom are preferred; a zirconium atom, a hafnium atom, a chromium atom, a nickel atom, a cobalt atom, a tin atom, an indium atom, a titanium atom, a ruthenium atom, a tantalum atom, a tungsten atom, an iron atom, a copper atom, a zinc atom, an aluminum atom, a gallium atom, a thallium atom and a bismuth atom are more preferred; and a zirconium atom, a hafnium atom, a zinc atom and an indium atom are still more preferred. Due to constituting the metal oxide from any of the aforementioned metal atoms, a more effective promotion of generation of the secondary electrons by the particles (A), and a further increase in the contrast of the rate of dissolution in the developer solution between the light-exposed regions and the light-unexposed regions of the film formed from the radiation-sensitive composition of the present embodiment are enabled. Either one type, or a combination of two or more types, of these metal atoms may be used as the metal atom constituting the metal oxide included in the particles (A).

The metal oxide may contain an additional atom, other than the metal atom and the oxygen atom. Examples of the additional atom include metalloid atoms such as a boron atom, a germanium atom, an antimony atom and a tellurium atom; a carbon atom; a hydrogen atom; a nitrogen atom; a phosphorus atom; a sulfur atom; a halogen atom; and the like. In the case of the metal oxide including the metalloid atom, the percentage content (% by mass) of the metalloid atom in the metal oxide is typically less than the percentage content of the metal atom.

The lower limit of the total percentage content of the metal atom and the oxygen atom in the metal oxide is preferably 5% by mass, more preferably 10% by mass, and still more preferably 25% by mass. Meanwhile, the upper limit of the total percentage content of the metal atom and the oxygen atom in the metal oxide is preferably 99.9% by mass, more preferably 80% by mass, and still more preferably 70% by mass. When the total percentage content of the metal atom and the oxygen atom falls within the above range, more effective promotion of the generation of the secondary electrons by the particles (A) is enabled, whereby the sensitivity of the radiation-sensitive composition can be further improved. It is to be noted that the total percentage content of the metal atom and the oxygen atom may be 100% by mass.

The metal oxide is exemplified by: a metal oxide constituted only of a metal atom and an oxygen atom; a metal oxide including a metal atom and an organic ligand including an oxygen atom; and the like. Exemplary metal oxide including a metal atom and an organic ligand is a compound including a repeating structure of: (metal atom-organic ligand-metal atom). As the organic ligand, a ligand derived from (a) an organic acid is preferred. Exemplary ligand derived from the organic acid (a) is an anion generated by eliminating one or a plurality of protons from the organic acid (a). The “organic acid” as referred to herein means an acidic organic compound, and the “organic compound” as referred to means a compound having at least one carbon atom.

When the particles (A) include the metal oxide that includes the metal atom and the ligand derived from the organic acid (a), further improvements of the sensitivity and resolution of the radiation-sensitive composition are enabled. Although not necessarily clarified and without wishing to be bound by any theory, the reason for achieving the effects described above due to the radiation-sensitive composition having the aforementioned constitution is inferred as in the following, for example. Specifically, it is considered that the ligand derived from the organic acid (a) being present in the vicinity of a surface of the particles (A) due to an interaction with the metal atom would improve the solubility of the particles (A) in the solvent. On the other hand, the base generated from the base-generating agent (B) in the light-exposed region upon exposure to the radioactive ray removes the ligand derived from the organic acid (a), from the particles (A) through a neutralization reaction and the like, leading to a decrease in the solubility of the particles (A) in the developer solution. In addition, removing the ligand derived from the organic acid (a) from the particles (A) promotes the aforementioned reactions similar to the sol-gel condensation reaction, resulting in a further decrease in the solubility of the particles (A) in the developer solution. The sensitivity of the radiation-sensitive composition is considered to be further improved as a result of the foregoing. In addition, the ligand derived from the organic acid (a) is believed to further improve the resolution of the radiation-sensitive composition by controlling in the film a phenomenon of diffusion of the base generated from the base-generating agent (B) in the light-exposed regions to allow for inhibition of undesired chemical reactions in the light-unexposed regions.

The lower limit of pKa of the organic acid (a) is preferably 0, more preferably 1, still more preferably 1.5, and particularly preferably 2. Meanwhile, the upper limit of the pKa is preferably 7, more preferably 6, still more preferably 5.5, and particularly preferably 5. When the pKa of the organic acid (a) falls within the above range, it is possible to adjust the interaction between the ligand derived from the organic acid (a) and the metal atom to be moderately weak, whereby further improvements of the sensitivity and resolution of the radiation-sensitive composition are enabled. Here, in the case of the organic acid (a) being a polyvalent acid, the pKa of the organic acid (a) as referred to means a primary acid dissociation constant, i.e., a logarithmic value of a dissociation constant for dissociation of the first proton.

The organic acid (a) may be either a low molecular weight compound or a high molecular weight compound, and a low molecular weight compound is preferred in light of adjusting the interaction with the metal atom to be more appropriately weak. The “low molecular weight compound” as referred to herein means a compound having a molecular weight of no greater than 1,500, whereas the “high molecular weight compound” as referred herein to means a compound having a molecular weight of greater than 1,500. The lower limit of the molecular weight of the organic acid (a) is preferably 50, and more preferably 70. Meanwhile, the upper limit of the molecular weight is preferably 1,000, more preferably 500, still more preferably 400, and particularly preferably 300. When the molecular weight of the organic acid (a) falls within the above range, it is possible to adjust the solubility of the particles (A) in the developer solution to be more appropriate, whereby the sensitivity and resolution of the radiation-sensitive composition can be further improved.

The organic acid (a) is exemplified by a carboxylic acid, a sulfonic acid, a sulfinic acid, an organic phosphinic acid, an organic phosphonic acid, a phenol, an enol, a thiol, an acid imide, an oxime, a sulfonamide, and the like.

Examples of the carboxylic acid include:

monocarboxylic acids such as formic acid, acetic acid, propionic acid, butanoic acid, pentanoic acid, hexanoic acid, heptanoic acid, octanoic acid, nonanoic acid, decanoic acid, 2-ethylhexanoic acid, oleic acid, acrylic acid, methacrylic acid, trans-2,3-dimethylacrylic acid, stearic acid, linoleic acid, linolenic acid, arachidonic acid, salicylic acid, benzoic acid, p-aminobenzoic acid, iodobenzoic acid (for example, 2-iodobenzoic acid, 3-iodobenzoic acid, 4-iodobenzoic acid, etc.), monochloroacetic acid, dichloroacetic acid, o-toluic acid, m-toluic acid, p-toluic acid, trifluoroacetic acid, pentafluoropropionic acid, gallic acid and shikimic acid;

dicarboxylic acids such as oxalic acid, malonic acid, maleic acid, methylmalonic acid, fumaric acid, adipic acid, sebacic acid, phthalic acid and tartaric acid; carboxylic acids having no less than 3 carboxy groups such as citric acid; and the like.

Examples of the sulfonic acid include benzenesulfonic acid, p-toluenesulfonic acid, and the like.

Examples of the sulfinic acid include benzenesulfinic acid, p-toluenesulfinic acid, and the like.

Examples of the organic phosphinic acid include diethylphosphinic acid, methylphenylphosphinic acid, diphenylphosphinic acid, and the like.

Examples of the organic phosphonic acid include methylphosphonic acid, ethylphosphonic acid, t-butylphosphonic acid, cyclohexylphosphonic acid, phenylphosphonic acid, and the like.

Examples of the phenol include: monovalent phenols such as phenol, cresol, 2,6-xylenol and naphthol; divalent phenols such as catechol, resorcinol, hydroquinone and 1,2-naphthalenediol; phenols having a valency of no less than 3 such as pyrogallol and 2,3,6-naphthalenetriol; and the like.

Examples of the enol include 2-hydroxy-3-methyl-2-butene, 3-hydroxy-4-methyl-3-hexene, and the like.

Examples of the thiol include mercaptoethanol, mercaptopropanol, and the like.

Examples of the acid imide include:

carboxylic imides such as maleimide and succinimide;

sulfonic imides such as a di(trifluoromethanesulfonic acid) imide and di(pentafluoroethanesulfonic acid) imide; and the like.

Examples of the oxime include:

aldoximes such as benzaldoxime and salicylaldoxime;

ketoximes such as diethylketoxime, methylethylketoxime and cyclohexanoneoxime; and the like.

Examples of the sulfonamide include methylsulfonamide, ethylsulfonamide, benzenesulfonamide, toluenesulfonamide, and the like.

In light of further improving the sensitivity and resolution of the radiation-sensitive composition, as the organic acid (a), the carboxylic acid is preferred; the monocarboxylic acid is more preferred; and methacrylic acid, benzoic acid and m-toluic acid are still more preferred.

As the metal oxide, a metal oxide including zirconium and a ligand derived from methacrylic acid; a metal oxide including hafnium and a ligand derived from benzoic acid; a metal oxide including zinc and a ligand derived from methacrylic acid; a metal oxide including indium and a ligand derived from benzoic acid; and a metal oxide constituted of zirconium and oxygen atoms are preferred.

The lower limit of the percentage content of the metal oxide in the particles (A) is preferably 60% by mass, more preferably 80% by mass, and still more preferably 95% by mass. It is to be noted that the percentage content of the metal oxide may be 100% by mass. When the percentage content of the metal oxide is no less than the lower limit, further improvements of the sensitivity and resolution of the radiation-sensitive composition are enabled. It is to be noted that the particles (A) may include either only a single type, or two or more types, of the metal oxides.

The lower limit of the number of the metal atoms included in the particles (A) is preferably 2 and more preferably 4. Meanwhile, the upper limit of the number of the metal atoms included in the particles (A) is preferably 30, more preferably 10, and still more preferably 6. When the number of the metal atoms included in the particles (A) falls within the above range, further improvements of the sensitivity and resolution of the radiation-sensitive composition are enabled.

In the case of the particles (A) including the ligand derived from the organic acid (a), the lower limit of the percentage content of the ligand derived from the organic acid (a) in the particles (A) is preferably 1% by mass, more preferably 20% by mass, still more preferably 40% by mass, and particularly preferably 60% by mass. Meanwhile, the upper limit of the percentage content of the ligand derived from the organic acid (a) is preferably 95% by mass, and more preferably 90% by mass. When the percentage content of the ligand derived from the organic acid (a) falls within the above range, it is possible to adjust the solubility of the particles (A) in the developer solution to be more appropriate, whereby further improvements of the sensitivity and resolution of the radiation-sensitive composition are enabled. The particles (A) may include either only a single type, or two or more types, of the ligand derived from the organic acid (a).

The lower limit of the content of the particles (A) with respect to the total solid content in the composition is preferably 10% by mass, more preferably 50% by mass, still more preferably 70% by mass, and particularly preferably 85% by mass. Meanwhile, the upper limit of the content of the particles (A) with respect to the total solid content in the composition is preferably 99% by mass, and more preferably 95% by mass. When the content of the particles (A) falls within the above range, further improvements of the sensitivity and resolution of the radiation-sensitive composition are enabled. The radiation-sensitive composition may include either only a single type, or two or more types, of the particles (A). The “solid content” as referred to herein means a component obtained by removing the solvent (C) and an inorganic solvent (described later) from the radiation-sensitive composition.

### Synthesis Procedure of Particles (A)

The particles (A) may be obtained by, for example, a procedure of subjecting (b) a metal-containing compound to a hydrolytic condensation reaction, a procedure of subjecting the metal-containing compound (b) to a ligand substitution reaction, and the like. The “hydrolytic condensation reaction” as referred to herein means a reaction in which a hydrolyzable group included in the metal-containing compound (h) is hydrolyzed to give —OH, and two —OHs thus obtained undergo dehydrative condensation to form —O—.

### Metal-Containing Compound (b)

The metal-containing compound (b) is: a metal compound (I) having a hydrolyzable group; a hydrolysis product of the metal compound (I) having a hydrolyzable group; a hydrolytic condensation product of the metal compound (I) having a hydrolyzable group; or a combination thereof. The metal compound (I) may be used either alone of one type, or in combination of two or more types thereof.

The hydrolyzable group is exemplified by a halogen atom, an alkoxy group, an acyloxy group, and the like.

Examples of the halogen atom include a fluorine atom, a chlorine atom, a bromine atom, an iodine atom, and the like.

Examples of the alkoxy group include a methoxy group, an ethoxy group, a n-propoxy group, an i-propoxy group, a butoxy group, and the like.

Examples of the acyloxy group include an acetoxy group, an ethylyloxy group, a propionyloxy group, a n-butyryloxy group, a t-butyryloxy group, a t-amylyloxy group, a n-hexanecarbonyloxy group, a n-octanecarbonyloxy group, and the like.

As the hydrolyzable group, an alkoxy group and an acyloxy group are preferred, and an isopropoxy group and an acetoxy group are more preferred.

In a case in which the metal-containing compound (b) is a hydrolytic condensation product of the metal compound (I), the hydrolytic condensation product of the metal compound (I) may be a hydrolytic condensation product of the metal (I) having a hydrolyzable group with a compound including a metalloid atom, within a range not leading to impairment of the effects of the embodiments of the present invention. In other words, the hydrolytic condensation product of the metal compound (I) may also include a metalloid atom within a range not leading to impairment of the effects of the embodiments of the present invention. The metalloid atom is exemplified by a boron atom, a germanium atom, an antimony atom, a tellurium atom and the like. The percentage content of the metalloid atom in the hydrolytic condensation product of the metal compound (I) is typically less than 50 atom % with respect to the entirety of the metal atom and the metalloid atom in the hydrolytic condensation product. The upper limit of the percentage content of the metalloid atom is preferably 30 atom % and more preferably 10 atom % with respect to the entirety of the metal atom and the metalloid atom in the hydrolytic condensation product.

The metal compound (I) is exemplified by compounds represented by the following formula (1) (hereinafter, may be also referred to as a “metal compound (I-1)”), and the like. By using the metal compound (I-1), forming a stable metal oxide is enabled, whereby further improvements of the sensitivity and resolution of the radiation-sensitive composition are enabled.

LₐMY_{b} (1)

In the above formula (1), M represents a metal atom; L represents a ligand; a is an integer of 0 to 2, wherein in a case where a is 2, a plurality of Ls may be identical or different; Y represents a hydrolyzable group selected from a halogen atom, an alkoxy group, and an acyloxy group; and b is an integer of 2 to 6, wherein a plurality of Ys may be identical or different, and the ligand represented by L does not fall under the definition of Y.

The metal atom represented by M is exemplified by metal atoms similar to those exemplified in connection with the metal atoms constituting the metal oxide included in the particles (A), and the like.

The ligand represented by L is exemplified by a monodentate ligand and a polydentate ligand.

Exemplary monodentate ligand includes a hydroxo ligand, a carboxy ligand, an amido ligand, an amine ligand, a nitro ligand, ammonia, and the like.

Examples of the amido ligand include an unsubstituted amido ligand (NH₂), a methylamido ligand (NHMe), a dimethylamido ligand (NMe₂), a diethylamido ligand (NEt₂), a dipropylamido ligand (NPr₂), and the like. Examples of the amine ligand include a trimethylamine ligand, a triethylamine ligand, and the like.

Exemplary polydentate ligand includes a hydroxy acid ester, a β-diketone, a P-keto ester, a β-dicarboxylic acid ester, a hydrocarbon having a it bond, a diphosphine, and the like.

Examples of the hydroxy acid ester include glycolic acid esters, lactic acid esters, 2-hydroxycyclohexane-1-carboxylic acid esters, salicylic acid esters, and the like.

Examples of the β-diketone include 2,4-pentanedione, 3-methyl-2,4-pentanedione, 3-ethyl-2,4-pentanedione, and the like.

Examples of the β-keto ester include acetoacetic acid esters, α-alkyl-substituted acetoacetic acid esters, β-ketopentanoic acid esters, benzoylacetic acid esters, 1,3-acetonedicarboxylic acid esters, and the like.

Examples of the β-dicarboxylic acid ester include malonic acid diesters, α-alkyl-substituted malonic acid diesters, α-cycloalkyl-substituted malonic acid diesters, α-aryl-substituted malonic acid di esters, and the like.

Examples of the hydrocarbon having a π bond include:

chain olefins such as ethylene and propylene;

cyclic olefins such as cyclopentene, cyclohexene and norbornene;

chain dienes such as butadiene and isoprene;

cyclic dienes such as cyclopentadiene, methylcyclopentadiene, pentamethylcyclopentadiene, cyclohexadiene and norbornadiene;

aromatic hydrocarbons such as benzene, toluene, xylene, hexamethylbenzene, naphthalene and indene; and the like.

Examples of the diphosphine include 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, 1,1′-bis(diphenylphosphino)ferrocene, and the like.

Examples and preferred examples of the halogen atom, the alkoxy group and the acyloxy group that may be represented by Y may be similar to those explained in connection with the hydrolyzable group.

Preferably, b is an integer of 2 to 4, and more preferably 4. When b is the above-specified value, it is possible to increase the percentage content of the metal oxide in the particles (A), whereby more effective promotion of the generation of the secondary electrons by the particles (A) is enabled. Consequently, a further improvement of the sensitivity of the radiation-sensitive composition is enabled.

As the metal-containing compound (h), a metal alkoxide that is neither hydrolyzed nor hydrolytic condensed, and a metal acyloxide that is neither hydrolyzed nor hydrolytically condensed are preferred.

Examples of the metal-containing compound (b) include zirconium(IV) n-butoxide, zirconium(IV) n-propoxide, zirconium(IV) isopropoxide, hafnium(IV) ethoxide, indium(III) isopropoxide, hafnium(IV) isopropoxide, tantalum(V) ethoxide, tungsten(V) methoxide, tungsten(VI) ethoxide, iron chloride, zinc acetate dihydrate, titanium(VI) n-butoxide, titanium(IV) n-propoxide, zirconium(VI) di-n-butoxide bis(2,4-pentanedionate), titanium(VI) tri-n-butoxide stearate, bis(cyclopentadienyl)hafnium dichloride, bis(cyclopentadienyl)tungsten dichloride, diacetato [(S)-(−)-2,2′-bis(diphenylphosphino)-1,1′-binaphtyl]ruthenium, dichloro[ethylenebis(diphenylphosphine)]cobalt, a titanium butoxide oligomer, aminopropyltrimethoxytitanium, aminopropyltriethoxyzirconium, 2-(3,4-epoxycyclohexyl)ethyltrimethoxyzirconium, γ-glycidoxypropyltrimethoxyzirconium, 3-isocyanopropyltrimethoxyzirconium, 3-isocyanopropyltriethoxyzirconium, triethoxymono(acetylacetonato)titanium, tri-n-propoxymono (acetylacetonato)titanium, tri-i-propoxymono(acetylacetonato)titanium, triethoxymono(acetylacetonato)zirconium, tri-n-propoxymono(acetylacetonato)zirconium, tri-i-propoxymono(acetylacetonato)zirconium, diisopropoxybis(acetylacetonato)titanium, di-n-butoxybis(acetylacetonato)titanium, di-n-butoxybis(acetylacetonato)zirconium, tri(3-methacryloxypropyl)methoxyzirconium, tri(3-acryloxypropyl)methoxyzirconium, and the like. Of these, zirconium(IV) isopropoxide, hafnium(IV) isopropoxide, zinc acetate dihydrate, and indium(III) isopropoxide are preferred.

A procedure for subjecting the metal-containing compound (b) to the hydrolytic condensation reaction may be exemplified by: a procedure of hydrolytically condensing the metal-containing compound (b) in a solvent containing water; and the like. In this case, other compound having a hydrolyzable group may be added as needed. The lower limit of the amount of water used for the hydrolytic condensation reaction is preferably 0.2 times molar amount, more preferably an equimolar amount, and still more preferably 3 times molar amount with respect to the hydrolyzable group included in the metal-containing compound (b) and the like. The upper limit of the amount of water is preferably 20 times molar amount, more preferably 15 times molar amount, and still more preferably 10 times molar amount with respect to the hydrolyzable group included in the metal-containing compound (b) and the like. When the amount of the water in the hydrolytic condensation reaction falls within the above range, it is possible to increase the percentage content of the metal oxide in the particles (A) to be obtained, whereby further improvements of the sensitivity and resolution of the radiation-sensitive composition are enabled. It is to be noted that the hydrolytic condensation reaction may proceed even with a small amount of water with which the solvent has been inevitably contaminated, and it is therefore not necessarily required to especially add water into the solvent.

A procedure for subjecting the metal-containing compound (b) to the ligand substitution reaction may be exemplified by: a procedure of mixing the metal-containing compound (b) and the organic acid (a); and the like. In this case, mixing of the organic acid (a) and the metal-containing compound (b) may be performed either in a solvent or without a solvent. Upon the mixing, a base such as triethylamine may be added as needed. The amount of the base added is, for example, no less than 1 part by mass and no greater than 200 parts by mass with respect to 100 parts by mass of a total amount of the metal-containing compound (b) and the organic acid (a) used.

In the case of using an organic acid (a) for synthesizing the particles (A), the lower limit of the amount of the organic acid (a) used is preferably 10 parts by mass, and more preferably 30 parts by mass, with respect to 100 parts by mass of the metal-containing compound (b). Meanwhile, the upper limit of the amount of the organic acid (a) used is preferably 2,000 parts by mass, more preferably 1,000 parts by mass, still more preferably 700 parts by mass, and particularly preferably 100 parts by mass, with respect to 100 parts by mass of the metal-containing compound (b). When the amount of the organic acid (a) used falls within the above range, it is possible to appropriately adjust the percentage content of the ligand derived from the organic acid (a) in the particles (A) to be obtained, whereby further improvements of the sensitivity and resolution of the radiation-sensitive composition are enabled.

Upon the synthesis reaction of the particles (A), in addition to the metal compound (I) and the organic acid (a), a compound that may be the polydentate ligand represented by L in the compound of the formula (1), a compound that may be a bridging ligand, etc., may also be added. The compound that may be the bridging ligand is exemplified by a compound having a hydroxy group, an isocyanate group, an amino group, an ester group and an amide group in a plurality of number, and the like.

The solvent for use in the synthesis reaction of the particles (A) is not particularly limited, and solvents similar to those exemplified in connection with the solvent (C) described later may be used. Of these, alcohol solvents, ether solvents, ester solvents, and hydrocarbon solvents are preferred; alcohol solvents, ether solvents and ester solvents are more preferred; polyhydric alcohol partial ether solvents, monocarboxylic acid ester solvents and cyclic ether solvents are still more preferred; propylene glycol monoethyl ether, ethyl acetate and tetrahydrofuran are particularly preferred.

In the case of using the solvent in the synthesis reaction of the particles (A), the solvent used may be either removed after the completion of the reaction, or directly used as the solvent (C) in the radiation-sensitive composition without removal thereof.

The lower limit of the temperature of the synthesis reaction of the particles (A) is preferably 0° C., and more preferably 10° C. Meanwhile, the upper limit of the temperature is preferably 150° C., and more preferably 100° C.

The lower limit of the time period of the synthesis reaction of the particles (A) is preferably 1 min, more preferably 10 min, and still more preferably 1 hour. The upper limit of the time period is preferably 100 hrs, more preferably 50 hrs, and still more preferably 24 hrs.

### (B) Base-Generating Agent

The base-generating agent (B) generates a base resulting from the secondary electrons generated from the particles (A) in the light-exposed regions. Due to the solubility of the particles (A) in the developer solution being changed by the base thus generated, pattern formation from the radiation-sensitive composition is enabled.

The base-generating agent (B) is exemplified by complexes of a transition metal such as cobalt (hereinafter, may be also referred to as “transition metal complex”), nitrobenzyl carbamates, α,α-dimethyl-3,5-dimethoxybenzyl carbamates, acyloxyiminos, and the like.

Examples of the transition metal complex include bromopentaammonium cobalt perchlorate, bromopentapropylamine cobalt perchlorate, hexaammonium cobalt perchlorate, hexakis(methylamine) cobalt perchlorate, hexakis(propylamine) cobalt perchlorate, and the like.

Examples of the nitrobenzyl carbamates include [[(2-nitrobenzyl)oxy]carbonyl]methylamine, [[(2-nitrobenzyl)oxy]carbonyl]propylamine, [[(2-nitrobenzyl)oxy]carbonyl]hexylamine, [[(2-nitrobenzyl)oxy]carbonyl]cyclohexylamine, [[(2-nitrobenzyl)oxy]carbonyl]aniline, [[(2-nitrobenzyl)oxy]carbonyl]piperidine, bis[[(2-nitrobenzyl)oxy]carbonyl]hexamethylenediamine, bis[[(2-nitrobenzyl)oxy]carbonyl]phenylenediamine, bis[[(2-nitrobenzyl)oxy]carbonyl]toluenediamine, bis[[(2-nitrobenzyl)oxy]carbonyl]diaminodiphenylmethane, bis[[(2-nitrobenzyl)oxy]carbonyl]piperazine, [[(2,6-dinitrobenzyl)oxy]carbonyl]methylamine, [[(2,6-dinitrobenzyl)oxy]carbonyl]propylamine, [[(2,6-dinitrobenzyl)oxy]carbonyl]hexylamine, [[(2,6-dinitrobenzyl)oxy]carbonyl]cyclohexylamine, [[(2,6-dinitrobenzyl)oxy]carbonyl]aniline, [[(2,6-dinitrobenzyl)oxy]carbonyl]piperidine, bis[[(2,6-dinitrobenzyl)oxy]carbonyl]hexamethylenediamine, bis[[(2,6-dinitrobenzyl)oxy]carbonyl]phenylenediamine, bis[[(2,6-dinitrobenzyl)oxy]carbonyl]toluenediamine, bis[[(2,6-dinitrobenzyl)oxy]carbonyl]diaminodiphenylmethane, bis[[(2,6-dinitrobenzyl)oxy]carbonyl]piperazine, 2-nitrophenylmethyl 4-hydroxypiperidine-1-carboxylate, 2-nitrophenylmethyl 4-methacryloyloxypiperidine-1-carboxylate, and the like.

Examples of the α,α-dimethyl-3,5-dimethoxybenzyl carbamates include [[(α,α-dimethyl-3,5-dimethoxybenzyl)oxy]carbonyl]methylamine, [[(α,α-dimethyl-3,5-dimethoxybenzyl)oxy]carbonyl]propylamine, [[(α,α-dimethyl-3,5-dimethoxybenzyl)oxy]carbonyl]hexylamine, [[(α,α-dimethyl-3,5-dimethoxybenzyl)oxy]carbonyl]cyclohexylamine, [[(α,α-dimethyl-3,5-dimethoxybenzyl)oxy]carbonyl]aniline, [[(α,α-dimethyl-3,5-dimethoxybenzyl)oxy]carbonyl]piperidine, bis[[(α,α-dimethyl-3,5-dimethoxybenzyl)oxy]carbonyl]hexamethylenediamine, bis[[(α,α-dimethyl-3,5-dimethoxybenzyl)oxy]carbonyl]phenylenediamine, bis[[(α,α-dimethyl-3,5-dimethoxybenzyl)oxy]carbonyl]toluenediamine, bis[[(α,α-dimethyl-3,5-dimethoxybenzyl)oxy]carbonyl]diaminodiphenylmethane, bis[[(α,α-dimethyl-3,5-dimethoxybenzyl)oxy]carbonyl]piperazine, and the like.

Examples of the acyloxyiminos include propionylacetophenone oxime, propionylbenzophenone oxime, propionylacetone oxime, butyrylacetophenone oxime, butyrylbenzophenone oxime, butyrylacetone oxime, adipoylacetophenone oxime, adipoylbenzophenone oxime, adipoylacetone oxime, acroylacetophenone oxime, acroylbenzophenone oxime, acroylacetone oxime, and the like.

As the base-generating agent (B), in addition to the aforementioned compounds, for example, 2-nitrobenzyl cyclohexylcarbamate, O-carbamoyl hydroxyamide, 9-anthrylmethyl N,N-diethylcarbamate, 1-(anthraquinon-2-yl)ethyl imidazole-1-carboxylate, 1 ,2-diisopropyl-3-[bis(dimethylamino)methylene]guanidium 2-(3-benzoylphenyl)propionate, 1,2-dicyclohexyl-4,4,5,5-tetramethylbiguanidium n-butyltriphenylborate, (E)-1-piperidino-3-(2-hydroxyphenyl)-2-propene-1-one, or the like may also be used.

As the base-generating agent (B), a commercially available product, for example, of WPBG series (available from Wako Pure Chemical Industries, Ltd.) such as WPBG-018, WPBG-027, WPBG-140, WPBG-165, WPBG-266 and WPBG-300, or the like may also be used.

The base-generating agent (B) is preferably the nitrobenzyl carbamate, and more preferably 2-nitrophenylmethyl 4-hydroxypiperidine-1-carboxylate or 2-nitrophenylmethyl 4-methacryloyloxypiperidine-1-carboxylate.

The lower limit of the content of the base-generating agent (B) with respect to the total solid content in the radiation-sensitive composition is preferably 0.5% by mass, more preferably 1% by mass, and still more preferably 3% by mass. Meanwhile, the upper limit of the content of the base-generating agent (B) with respect to the total solid content in the composition is preferably 50% by mass, more preferably 30% by mass, and still more preferably 20% by mass. When the content of the base-generating agent (B) falls within the above range, further improvements of the sensitivity and resolution of the radiation-sensitive composition are enabled. The radiation-sensitive composition may include either a single type, or two or more types, of the base-generating agent (B).

### (C) Solvent

The solvent (C), which is a favorable component of the radiation-sensitive composition, is not particularly limited as long as it is a solvent capable of dissolving or dispersing at least the particles (A), the base-generating agent (B), as well as optional component(s) that may be included as needed. The solvent used in the synthesis of the particles (A) may also be directly used as the solvent (C). The radiation-sensitive composition may include either only a single type, or two or more types, of the solvent (C). It is to be noted that although the radiation-sensitive composition may further include an inorganic solvent such as water in addition to the solvent (C), it is preferred that the inorganic solvent is not contained as a principal solvent, in light of coating properties on a substrate, solubility of the particles (A) in a developer solution, storage stability, etc. The upper limit of the content of the inorganic solvent in the radiation-sensitive composition is preferably 20% by mass, and more preferably 10% by mass.

The solvent (C) is exemplified by an alcohol solvent, an ether solvent, a ketone solvent, an amide solvent, an ester solvent, a hydrocarbon solvent, and the like.

Examples of the alcohol solvent include:

aliphatic monohydric alcohol solvents having 1 to 18 carbon atoms such as 2-propanol, 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol monomethyl ether and propylene glycol monoethyl ether; and the like.

Examples of the ether solvent include:

dialkyl ether solvents such as diethyl ether, dipropyl ether, dibutyl ether, dipentyl ether, diisoamyl ether, dihexyl ether and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone and trimethyl nonanone;

cyclic ketone solvents such as cyclopentanone, cyclohexanone, cycloheptanone, cyclooctanone and methylcyclohexanone; 2,4-pentanedionc; acetonylacetone; acetophenone; and the like.

Examples of the amide solvent include: cyclic amide solvents such as N,N′-dimethylimidazolidinone and N-methylpyrrolidone; chain amide solvents such as N-methylformamide, N,N-dimethylformamide, N,N-diethylformamide, acetamide, N-methylacetamide, N,N-dimethylacetamide and N-methylpropionamide; and the like.

Examples of the ester solvent include:

monocarboxylic acid ester solvents such as ethyl acetate, n-butyl acetate and ethyl lactate; polyhydric alcohol carboxylate solvents such as propylene glycol acetate;

polyhydric alcohol partial ether carboxylate solvents such as propylene glycol monoethyl ether acetate; polyhydric carboxylic acid diester solvents such as diethyl oxalate;

lactone solvents such as γ-butyrolactone and δ-valerolactone;

carbonate solvents such as dimethyl carbonate, diethyl carbonate, ethylene carbonate and propylene carbonate; and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene, xylene, decahydronaphthalene; and the like.

As the solvent (C), the ester solvent is preferred; the polyhydric alcohol partial ether carboxylate solvent and the polyhydric alcohol partial ether solvent are preferred; and propylene glycol monomethyl ether acetate and propylene glycol monomethyl ether are still more preferred.

### Other Optional Component

The radiation-sensitive composition may also include, in addition to the components (A) to (C), optional components such as a compound that may be a ligand, a surfactant, and the like.

Compound that may be Ligand

The compound that may be a ligand to be used in the radiation-sensitive composition is exemplified by a compound that may be a polydentate ligand or a bridging ligand (hereinafter, may be also referred to as “compound (II)”) and the like. Examples of the compound (II) include compounds similar to those exemplified in connection with the synthesis procedure of the particles (A), and the like.

In the case in which the radiation-sensitive composition contains the compound (II), the upper limit of the content of the compound (II) with respect to the total solid content in the radiation-sensitive composition is preferably 10% by mass, more preferably 3% by mass, and still more preferably 1% by mass.

### Surfactant

The surfactant which may be used in the radiation-sensitive composition is a component that exhibits the effect of improving coating properties, striation and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate; and the like. Examples of a commercially available product of the surfactant include KP341 (manufactured by Shin-Etsu Chemical Co., Ltd.), Polyflow No. 75 and Polyflow No. 95 (each manufactured by Kyoeisha Chemical Co., Ltd.), EFTOP EF301, EFTOP EF303 and EFTOP EF352 (each manufactured by Tochem Products Co. Ltd.), Megaface F171 and Megaface F173 (each manufactured by DIC Corporation), Fluorad FC430 and Fluorad FC431 (each manufactured by Sumitomo 3M Limited), ASAHI GUARD AG710, Surflon S-382, Surflon SC-101, Surflon SC-102, Surflon SC-103, Surflon SC-104, Surflon SC-105 and Surflon SC-106 (each manufactured by Asahi Glass Co., Ltd.), and the like.

### Preparation Method of Radiation-Sensitive Composition

The radiation-sensitive composition may be prepared, for example, by mixing the particles (A) and the base-generating agent (B), as well as the other optional component such as the solvent (C) as needed, at a certain ratio, preferably followed by filtering a thus resulting mixture through a membrane filter having a pore size of 0.2 μm. In the case of the radiation-sensitive composition including the solvent (C), the lower limit of the solid content concentration of the radiation-sensitive composition is preferably 0.1% by mass, more preferably 0.5% by mass, still more preferably 1% by mass, and particularly preferably 3% by mass. The upper limit of the solid content concentration is preferably 50% by mass, more preferably 30% by mass, still more preferably 15% by mass, and particularly preferably 7% by mass.

### Pattern-Forming Method

The pattern-forming method of another embodiment of the present invention includes: applying the radiation-sensitive composition on one face side of a substrate to form a film (hereinafter, may be also referred to as “applying step”); exposing the film (hereinafter, may be also referred to as “exposure step”); and developing the film exposed (hereinafter, may be also referred to as “development step”). The radiation-sensitive composition of the embodiment of the present invention described above is employed in the pattern-forming method, and therefore the method enables a pattern superior in resolution to be formed with high sensitivity. Hereinafter, each step is explained.

### Applying Step

In this step, the radiation-sensitive composition is applied on one face side of a substrate to form a film. Specifically, the film is formed by applying on one face side of a substrate the radiation-sensitive composition such that the resulting film has a desired thickness, followed by prebaking (PB) to volatilize the solvent (C) and the like in the radiation-sensitive composition as needed. A procedure for applying the radiation-sensitive composition is not particularly limited, and an appropriate application procedure such as spin-coating, cast coating, roller coating, etc. may be employed. Examples of the substrate include a silicon wafer, a wafer coated with aluminum, and the like. It is to be noted that an organic or inorganic antireflective film may also be formed beforehand on the substrate in order to maximize potential of the radiation-sensitive composition.

The lower limit of an average thickness of the film to be formed in this step is preferably 1 nm, more preferably 5 nm, still more preferably 10 nm, and particularly preferably 20 nm. Meanwhile, the upper limit of the average thickness is preferably 1,000 nm, more preferably 200 nm, still more preferably 100 nm, and particularly preferably 70 nm.

The lower limit of the temperature of the PB is typically 60° C., and preferably 80° C. The upper limit of the temperature of the PB is typically 140° C., and preferably 120° C. The lower limit of the time period of the PB is typically 5 sec, and preferably 10 sec. The upper limit of the time period of the PB is typically 600 sec, and preferably 300 sec.

In this step, in order to inhibit an influence of basic impurities, etc., in the environmental atmosphere, for example, a protective film may be provided on the film formed. Furthermore, in the case of conducting liquid immersion lithography in the exposing step as described later, in order to avoid a direct contact between a liquid immersion medium and the film, a protective film for liquid immersion may also be provided on the film fanned.

### Exposure Step

In this step, the film obtained after the applying step is exposed. Specifically, for example, the film is irradiated with a radioactive ray through a mask having a predetermined pattern. In this step, irradiation with a radioactive ray through a liquid immersion medium such as water, i.e., liquid immersion lithography, may be employed as needed. Examples of the radioactive ray for the exposure include: electromagnetic waves such as visible light rays, ultraviolet rays, far ultraviolet rays, EUV (wavelength: 13.5 nm), X-rays and γ-rays; charged particle rays such as electron beams and α-rays; and the like. Of these, EUV and electron beams are preferred in light of increasing the secondary electrons generated from the particles (A) having absorbed the radioactive ray.

### Development Step

In this step, the exposed film is developed by using a developer solution. A predetermined negative-tone pattern is thereby formed. Examples of the developer solution include an alkaline aqueous solution, an organic solvent-containing liquid, and the like. As the developer solution, the organic solvent-containing liquid is preferred in light of developability and the like.

Examples of the alkaline aqueous solution include alkaline aqueous solutions prepared by dissolving at least one alkaline compound such as sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, etc., and the like.

The lower limit of the content of the alkaline compound in the alkaline aqueous solution is preferably 0.1% by mass, more preferably 0.5% by mass, and still more preferably 1% by mass. The upper limit of the content of the alkaline compound is preferably 20% by mass, more preferably 10% by mass, and still more preferably 5% by mass.

As the alkaline aqueous solution, an aqueous TMAH solution is preferred, and a 2.38% by mass aqueous TMAH solution is more preferred.

Examples of the organic solvent in the organic solvent-containing liquid include organic solvents similar to those exemplified in connection with the solvent (C) in the radiation-sensitive composition, and the like. Of these, alcohol solvents are preferred, aliphatic monohydric alcohol solvents are more preferred, and 2-propanol is still more preferred.

The lower limit of the content of the organic solvent in the organic solvent-containing liquid is preferably 80% by mass, more preferably 90% by mass, still more preferably 95% by mass, and particularly preferably 99% by mass. When the content of the organic solvent falls within the above range, a further improvement of a contrast of the rate of dissolution in the developer solution between the light-exposed regions and the light-unexposed regions is enabled. Examples of components other than the organic solvent in the organic solvent-containing liquid include water, silicone oil, and the like.

An appropriate amount of a surfactant may be added to the developer solution as needed. As the surfactant, for example, an ionic or nonionic fluorochemical surfactant, a silicone surfactant, or the like may be used.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously discharged onto the substrate that is rotated at a constant speed while scanning with a developer solution-discharge nozzle at a constant speed; and the like.

It is preferred that, following the development, the substrate is rinsed by using a rinse agent such as water, alcohol, etc., and then dried. A procedure for the rinsing is exemplified by a procedure of continuously discharging the rinse agent onto the substrate that is rotated at a constant speed (spin-coating procedure), a procedure of immersing the substrate for a given time period in the rinse agent charged in a container (dipping procedure), a procedure of spraying the rinse agent onto the surface of the substrate (spraying procedure), and the like.

### EXAMPLES

Hereinafter, the present invention is explained in detail by way of Examples, but the present invention is not limited to these Examples. Measuring methods for physical properties in connection with the Examples are shown below.

### Mean Particle Diameter

The mean particle diameter of the particles (A) was determined by a DLS method using a light scattering measurement device (“Zetasizer Nano ZS” available from Malvern Instruments Ltd.).

### (A) Particles

The particles (A) were synthesized by the following procedure. The organic acids (a) and the metal-containing compounds (b) used for the synthesis of the particles (A) are shown below.

### Organic Acid (a)

a-1: methacrylic acid (pKa: 4.66)

a-2: benzoic acid (pKa: 4.21)

### Metal-Containing Compound (b)

b-1: tetraethoxysilane

b-2: zirconium(IV) isopropoxide

b-3: hafnium(IV).isopropoxide

b-4: zinc acetate dihydrate

b-5: indium(III) isopropoxide

### Synthesis Example 1

In 9.0 g of the compound (a-1), 1.3 g of the compound (b-1) and 0.3 g of the compound (b-2) were dissolved, and the resulting solution was heated at 65° C. for 12 hrs. The reaction solution was washed with ultra pure water and acetone and then dried to give metal oxide particles (A-1) including principally the metalloid atoms, the metal atoms, and the ligand derived from the organic acid. The mean particle diameter of the particles (A-1) was 4.1 nm.

### Synthesis Example 2

18 g of the compound (a-1) and 3 g of the compound (b-2) were blended and the resulting solution was heated at 65° C. for 21 hrs. The reaction solution was washed with ultra pure water and acetone and then dried to give metal oxide particles (A-2) including principally the metal atoms and the ligand derived from the organic acid. The mean particle diameter of the particles (A-2) was 2.1 nm.

### Synthesis Example 3

In 30.0 g of tetrahydrofuran (THF), 2.5 g of the compound (a-2) and 1.5 g of the compound (b-3) were dissolved, and the resulting solution was heated at 65° C. for 21 hrs. The reaction solution was washed with ultra pure water and acetone and then dried to give metal oxide particles (A-3) including principally the metal atoms and the ligand derived from the organic acid. The mean particle diameter of the particles (A-3) was 2.3 nm.

### Synthesis Example 4

In 40.0 g of ethyl acetate, 1.9 g of the compound (a-1) and 1.7 g of the compound (b-4) were dissolved. 2.2 ml of triethylamine was added dropwise thereto and the resulting solution was heated at 65° C. for 2 hrs. The reaction solution was washed with hexane and then dried to give metal oxide particles (A-4) including principally the metal atoms and the ligand derived from the organic acid. The mean particle diameter of the particles (A-4) was 1.6 nm.

### Synthesis Example 5

In 3.7 g of propylene glycol monoethyl ether, 50 mg of the compound (a-2) and 60 mg of the compound (b-5) were dissolved. A reaction in the resulting solution was allowed at room temperature for 30 min to give a dispersion liquid of particles (A-5) including principally the metal atoms and the ligand derived from the organic acid. The mean particle diameter of the particles (A-5) was 1.9 nm.

### Synthesis Example 6

One g of the compound (b-2) was dissolved in tetrahydrofuran (THF). Thereto was added 3.3 ml of triethylamine dropwise, and the resulting solution was heated at 65° C. for 4 hrs. The reaction solution was washed with ultra pure water and acetone and then dried to give metal oxide particles (A-6) including principally the metal atoms and oxygen atom. The mean particle diameter of the particles (A-6) was 3.5 nm.

### Preparation of Radiation-Sensitive Composition

The base-generating agent (B), the acid-generating agent (B′), and the solvent (C) which were used in the preparation of the radiation-sensitive composition are shown below.

### (B) Base-Generating Agent and (B′) Acid-Generating Agent

B-1: 2-nitrophenylmethyl 4-hydroxypiperidine-1-carboxylate

B-2: 2-nitrophenylmethyl 4-methacryloyloxypiperidine-1-carboxylate

B′-1: N-hydroxynaphthalimide triflate

### (C) Solvent

C-1: propylene glycol monomethyl ether acetate

C-2: propylene glycol monoethyl ether

### Comparative Example 1

A mixed liquid having a solid content concentration of 5% by mass was provided by mixing 100 parts by mass of the particles (A-1), 5 parts by mass of (B′-1) as the acid-generating agent, and (C-1) as the solvent (C). The mixed liquid was filtered through a membrane filter having a pore size of 0.20 μm to prepare a radiation-sensitive composition (R-1) of Comparative Example 1.

### Comparative Examples 2 to 6 and Examples 1 to 5

Radiation-sensitive compositions of Comparative Examples 2 to 6 and Examples 1 to 5 (R-2) to (R-11) were prepared by a similar operation to that of Comparative Example 1 except that the type and the amount of each component used were as shown in Table 1 below. The symbol “−” in Table 1 indicates that the corresponding component was not used. The content of (A-5) is a value in terms of solid content equivalent. In addition, the percentage content of the metal atoms with respect to an entirety of metal atoms and metalloid atoms included in the radiation-sensitive compositions (R-2) to (R-5) and (R-7) to (R-11) was no less than 100 atom %. On the other hand, the percentage content of the metal atoms in the radiation-sensitive compositions (R-1) and (R-6) was 13 atom %. It is to be noted that the percentage content of the metal atom is an estimated value based on an assumption that all of the metal atoms included in each radiation-sensitive composition were derived from the particles (A) and that each metal atom included in the metal-containing compound (b) was used for the synthesis of the particles (A) in equal ratio. Specifically, the percentage content of the metal atom is a value obtained by 100×R_{B}/R_{A}, wherein R_{A} represents the number of atoms of the metal atoms and the metalloid atoms included in the metal-containing compound (b) used for the synthesis of the particles (A), and R_{B} represents the number of atoms of the metal atoms included in the metal-containing compound (b).

TABLE 1

| | | | | (B) Base- | | |
|---|---|---|---|---|---|---|
| | | | | generating | | |
| | | | | agent or | | |
| | | | | (B′) Acid- | | |
| | | | | generating | | |
| | | (A) Particles | | agent | | |
| | Radiation- | | content | | content | (C) |
| | sensitive | | (parts by | | (parts by | Solvent |
| | composition | type | mass) | type | mass) | type |
| Comparative | R-1 | A-1 | 100 | B′-1 | 5 | C-1 |
| Example 1 | | | | | | |
| Comparative | R-2 | A-2 | 100 | B′-1 | 5 | C-1 |
| Example 2 | | | | | | |
| Comparative | R-3 | A-3 | 100 | — | — | C-1 |
| Example 3 | | | | | | |
| Comparative | R-4 | A-4 | 100 | B′-1 | 10 | C-1 |
| Example 4 | | | | | | |
| Comparative | R-5 | A-5 | 100 | — | — | C-2 |
| Example 5 | | | | | | |
| Comparative | R-6 | A-1 | 100 | B-1 | 5 | C-1 |
| Example 6 | | | | | | |
| Example 1 | R-7 | A-2 | 100 | B-1 | 5 | C-1 |
| Example 2 | R-8 | A-3 | 100 | B-2 | 5 | C-1 |
| Example 3 | R-9 | A-4 | 100 | B-1 | 10 | C-1 |
| Example 4 | R-10 | A-5 | 100 | B-2 | 5 | C-2 |
| Example 5 | R-11 | A-6 | 100 | B-2 | 5 | C-2 |

### Pattern Formation

### Comparative Examples 1 to 6 and Examples 1 to 5

The radiation-sensitive compositions (R-1) to (R-11) prepared in Examples 1 to 5 and Comparative Examples 1 to 6 were each spin-coated onto a silicon wafer by a simplified spin coater, and then subjected to PB at 100° C. for 60 sec to form a film having an average thickness of 50 nm. Next, the film was exposed to an electron beam using an electron beam writer (“JBX-9500FS” available from JEOL Ltd.) to permit patterning. Subsequent to the exposure to the electron beam, the film was developed with 2-propanol and then dried to form a negative-tone pattern.

### Evaluations

The patterns thus formed were evaluated for the sensitivity and the limiting resolution by the method described below. The results are shown in Table 2.

### Sensitivity

An exposure dose, at which a line-and-space pattern (1L 1S) configured with line parts having a line width of 100 nm and space parts of 100 nm formed by neighboring line parts was formed to give a line width of 1:1, was defined as an “optimal exposure dose”, and the “optimal exposure dose” was defined as “sensitivity” (μC/cm²). The smaller value indicates superior sensitivity; and the sensitivity of less than 70 μC/cm² may be evaluated to be favorable, and the sensitivity of no less than 70 μC/cm² may be evaluated to be unfavorable.

### Limiting Resolution

Line-and-space patterns (1L 1S) were formed to have various line widths, and a half-pitch of the pattern in which a total of the line widths and the space widths was the smallest among the line-and-space patterns having the line width of 1:1 being maintained was defined as a limiting resolution (nm). The smaller value indicates superior limiting resolution; and the resolution of less than 55 nm may be evaluated to be favorable, and the limiting resolution of no less than 55 nm may be evaluated to be unfavorable.

TABLE 2

| | | PB | | Limiting |
|---|---|---|---|---|
| | Radiation-sensitive | temperature | Sensitivity | resolution |
| | composition | (° C.) | (μC/cm²) | (nm) |
| Comparative | R-1 | 100 | 70 | 80 |
| Example 1 | | | | |
| Comparative | R-2 | 100 | 60 | 70 |
| Example 2 | | | | |
| Comparative | R-3 | 100 | 60 | 60 |
| Example 3 | | | | |
| Comparative | R-4 | 100 | 50 | 60 |
| Example 4 | | | | |
| Comparative | R-5 | 100 | 50 | 55 |
| Example 5 | | | | |
| Comparative | R-6 | 100 | 70 | 75 |
| Example 6 | | | | |
| Example 1 | R-7 | 100 | 65 | 50 |
| Example 2 | R-8 | 100 | 60 | 50 |
| Example 3 | R-9 | 100 | 50 | 45 |
| Example 4 | R-10 | 100 | 45 | 45 |
| Example 5 | R-11 | 100 | 65 | 50 |

From the results shown in Table 2, it was confirmed that due to using the radiation-sensitive composition including: the particles (A) including the metal oxide as the principal component; and the base-generating agent (B), in which the percentage content of the metal atoms with respect to the entirety of the metal atoms and the metalloid atoms is no less than 50 atom %, formation of a fine pattern was enabled with superior resolution while maintaining the sensitivity. It is to be noted that an exposure to an electron beam is generally known to give a tendency similar to that in the case of the exposure to EUV. Therefore, the radiation-sensitive composition is expected to be superior in sensitivity and resolution also in the case of an exposure to EUV.

The radiation-sensitive composition and the pattern-forming method according to the embodiments of the present invention enable a pattern superior in resolution to be formed with high sensitivity. Therefore, these can be suitably used for a processing process of semiconductor devices, and the like, in which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

1. A radiation-sensitive composition comprising:
particles comprising a metal oxide as a principal component; and
a radiation-sensitive base-generating agent,
wherein a percentage content of metal atoms comprised in the composition with respect to an entirety of metal atoms and metalloid atoms comprised in the composition is no less than 50 atom %.

2. The radiation-sensitive composition according to claim 1, wherein a metal atom constituting the metal oxide comprises a zirconium atom, a hafnium atom, a chromium atom, a nickel atom, a cobalt atom, a tin atom, an indium atom, a titanium atom, a ruthenium atom, a tantalum atom, a tungsten atom, an iron atom, a copper atom, a zinc atom, an aluminum atom, a gallium atom, a thallium atom, a bismuth atom or a combination thereof.

3. The radiation-sensitive composition according to claim 1, wherein a content of the radiation-sensitive base-generating agent with respect to a total solid content in the composition is no less than 0.5% by mass and no greater than 50% by mass.

4. The radiation-sensitive composition according to claim 1, wherein a mean particle diameter of the particles is no greater than 20 nm.

5. A pattern-forming method comprising:
applying the radiation-sensitive composition according to claim 1 on one face side of a substrate to form a film;
exposing the film; and
developing the film exposed.

6. The pattern-forming method according to claim 5, wherein a developer solution used in the developing is an organic solvent-containing liquid.

7. The pattern-forming method according to claim 5, wherein a developer solution used in the developing is an alkaline aqueous solution.

8. The pattern-forming method according to claim 5, wherein a radioactive ray used in the exposing is an extreme ultraviolet ray or an electron beam.

9. The radiation-sensitive composition according to claim 1, wherein the metal oxide is constituted only of a metal atom and an oxygen atom, or constituted of a metal atom and an organic ligand comprising an oxygen atom.
